(19) United States
(12) Patent Application Publication
(10) Pub. No.: US 2010/0066382 A1
(43) Pub. Date: Mar. 18, 2010

(54) TEST DEVICE AND TEST METHOD FOR A PV CONCENTRATOR MODULE

(75) Inventor: Erich W. MERKLE, Munchen (DE)

Correspondence Address: FURR LAW FIRM, 2622 DEBOLT ROAD, UTICA, OH, 43080, US

(73) Assignee: SOLARTEC AG, Munchen (DE)

(21) Appl. No.: 12/159,767

(22) PCT Filed: Dec. 30, 2006
(86) PCT No.: PCT/DE2006/002338

§ 371 Date: Jun. 30, 2008

(30) Foreign Application Priority Data
Dec. 30, 2005 (DE) 10 2005 063 135.5
Jul. 27, 2006 (DE) 10 2006 034 793.5

(51) Int. Cl. G01R 31/00

(52) U.S. Cl. 324/501

(57) ABSTRACT

The invention relates to a test device for a PV concentrator module, comprising a first light source for generating a light that simulates solar irradiation, a lens system which concentrates the light beams emitted by the first light source to a pencil of rays whose individual light beams diverge by less than 2° while being suited to direct said pencil of rays to an incident light surface of the PV concentrator module, and an instrument for measuring an output signal of the PV concentrator module irradiated by the pencil of rays.

The invention relates to a test device for a PV concentrator module. Such a PV concentrator module is known for example from the article by A. W. Bett et al: FLATCON AND FLASHCON CONCEPTS FOR HIGH CONCENTRATION PV, Proc. 19th European Photovoltaic Solar Energy Conference and Exhibition, Paris, France, 2004, page 2488, and in a further developed form is the subject matter of the previously unpublished German patent application DE 10 2005 033 272.2 of the applicant. The invention also relates to a method for testing a PV concentrator module and to a method of production for such a PV concentrator module.

In the field of utilisation of solar energy, it has been known for some 50 years that solar energy can be converted into electrical current by silicon. For the most part, monocrystalline or multicrystalline silicon is used in the common solar cells of today. However, the power of these solar cells is relatively low as they only convert a limited spectrum of the incident radiation into electrical current. Great strides towards significantly higher efficiency with over 39% conversion of the solar radiation have been made in recent years with high-power PV cells made of higher grade semiconductor compounds (III-V semiconductor material) such as gallium arsenide (GaAs) for example.

Such cells based on semiconductor material can be built up in stages in the form of tandem cells, triple (corner) cells or multiple-stack cells and so use a broader light-frequency spectrum.

However, the production of such cells with large areas is very costly. Consequently, the approach that was chosen was to concentrate the incident sunlight on a very small area of less than 1 mm² for example. Then, a solar cell is only necessary for this small area. Then, the material used can be less than 1% compared with the area used for such cells. Concentration makes it possible to utilise the high light yield of high-power PV cells which is currently over 39%. As the combination of a plurality of solar units alone allows economic use of such a PV system, these are preferably combined to form a PV concentrator module.

The systems employed to date work mainly with relatively large Fresnel lenses with a relatively long focal length, leading to very thick modules. Combining these to form powerful units (solar power plants) leads to a very high weight (sometimes more than 1 ton weight per kilowatt) so that the requirements for the statics of a tracking system with which the PV modules can track the sunlight, are considerable due to the force of the wind for example. As a result, due to the high cost, the known concentrator systems have not been widely adopted in spite of the high growth in photovoltaic current generation.

In recent years concentrator systems have also been introduced with small optical systems which sometimes also allowed the sunlight to be concentrated by more than 500 times. However, in this case a large number of cells are necessary (e.g. approximately 1.5 million cells for 500 kW of power with 30% “output” from the solar cells), in order to produce a solar power plant which will operate economically. Until now, there have been problems with the external dissipation of high concentrations of heat and protection of the sensitive solar cells against environmental factors, in particular ingress of moisture and gases.

The possibility of testing a PV concentrator module prior to its assembly and testing the finished module to determine its efficiency and technical parameters remains unresolved. Conventional test devices cannot be employed as to test a PV concentrator module the light must impinge on the module being tested in standardised conditions (according to the angle of incidence of the sunlight). The performance parameters of a concentrator module can only be compared with those of other solar modules using such tests. Such test devices for concentrator modules with a large number of solar cells are not known at present.

The underlying object of the invention is to create a possibility for quality assurance for a PV concentrator module and in particular a possibility for testing the efficiency and/or other technical parameters of a PV concentrator module prior to final assembly and/or for testing the completed module after final assembly. A further object is to provide a test method for testing and a production method for producing a PV concentrator module so that a PV concentrator can be tested easily and produced with reliable quality.

This object is achieved through a test device according to the invention for a PV concentrator module with the features of claim 1 which is attached here.

Advantageous embodiments of the invention form the subject matter of the subordinate claims. A production method for a test device according to the invention and a test method for a PV concentrator module in each case form the subject matter of an accessory claim.

In one particularly preferred embodiment of the invention, the test device for a PV concentrator module is provided with one or more of the following elements: a positioning arrangement which can exhibit a direct current (DC) light source and/or at least one positioning mark, a light guide, in particular a quartz rod, a flash bulb which lights up coaxially with the direct current (DC) light source and the quartz rod, advantageously with an irradiance of around 1 kW/m², and/or a lens, such as for example a Fresnel lens, with a light outlet area which is greater than or equal to a light admission area of a PV concentrator module to be tested, for converting the bundle of light into a bundle of quasi-parallel light rays. In addition, a neutral grey filter can be provided for converting the bundle of quasi-parallel light rays into a bundle of quasi-parallel light rays with a quasi-uniform areal distribution of its irradiance, plus in each case a mains power connection both for the direct current (DC) light source and for the flash bulb, an electronic circuit for switching the PV concentrator module to be tested and/or a measuring device for recording of characteristics such as for example a current-voltage characteristic of the PV concentrator module to be tested. The direct current (DC) light source can be employed for precise positioning of the PV concentrator module to be tested with its light admission area inside the light admission area of the Fresnel lens of the test device using conventional positioning marks for example.

The use of a flash bulb with an irradiance of 1 kW/m² as a first light source of the test device according to the invention makes it possible to generate light with the spectrum of sunlight and a maximum irradiance which is comparable with the irradiance of sunlight in summer at midday with a cloudless sky.

The use of a diaphragm makes it possible to select from the rays coming from the flash bulb a bundle which nowhere exhibits an irradiance which is greatly dependent on the irradiance of the flash bulb.

When the diaphragm or the flash bulb is positioned roughly at the focal length of the Fresnel lens on its plane side not far from its optical axis, the use of a lens, such as the Fresnel lens, makes it possible to convert the bundle of light rays selected by the diaphragm into a bundle of quasi-parallel light rays.

The use of a neutral grey filter, such as for example a grid film, makes it possible to convert the bundle of quasi-parallel light rays into a bundle of quasi-parallel rays which exhibits a quasi-uniform areal distribution of its irradiance.

As the solar cells use the direct radiation of the sunlight, in a test method it is also advantageous to illuminate them with light with similar properties to those of direct radiation, e.g. with bundles of light rays with the same spectrum, similar divergence and similar areal distribution of illuminance.

The use of a Fresnel lens with an area which is equal to or greater than the light admission area of a PV concentrator module to be tested, makes it possible to illuminate the entire light admission area of the PV concentrator module to be tested with light coming from the test device. Thus, in a test method, it is possible to illuminate all the solar cells used in a PV concentrator module to be tested in exactly the same way as would be the case when used in a solar plant. The direct current (DC) light source, such as an LED for example, can be positioned quasi-coaxially with the flash bulb and the Fresnel lens on the other side of the flash bulb to the Fresnel lens using conventional positioning methods such as for example positioning marks. A PV concentrator module to be tested can be positioned by means of the direct current (DC) light source and/or conventional positioning methods such as for example positioning marks, so that its light admission area is located inside or precisely in alignment with the light outlet area of the Fresnel lens or the test device for complete illumination with light coming from the flash bulb of the test device.

Preferably, a quartz rod which is located between the direct current (DC) light source and the flash bulb and can be arranged coaxially with these, is used as light guide for the direct current (DC) light source, such as an LED for example, so as to be able to position the field of illumination of this light source coaxially with that of the flash bulb. In addition, the use of the quartz rod or a comparable light guide made of highly insulating material is advantageous due to the high voltage which has to be used to operate the flash bulb. For the power supply for the flash bulb and the direct current (DC) light source, the test device preferably exhibits mains power connections for the flash bulb and/or for the direct current (DC) light source.

In order to be able to measure current-voltage characteristics of a PV concentrator module to be tested by means of the test device according to the invention, this can exhibit a measuring device and a connecting arrangement, such as for example an electronic circuit, for connecting a PV concentrator module to be tested.

Advantageously, the test device according to the invention can exhibit a reflecting mirror which is positioned between the diaphragm and the Fresnel lens. The use of such a mirror allows the light coming from the flash bulb to be deflected. The deflection of the light makes it possible to illuminate a larger area of the Fresnel lens than would be possible when illuminating this without a reflecting mirror from the same distance. This makes it possible to produce smaller and therefore less expensive test devices.

In one preferred embodiment, the test device according to the invention can exhibit a filter which is arranged between the diaphragm and the Fresnel lens or between the diaphragm and the reflecting mirror parallel with the diaphragm. The use of such a filter allows easy alteration or adjustment of the illuminance or the light spectrum of the light coming from the flash bulb through the diaphragm in order to eliminate undesired deviations in the illuminance or the light frequency of the light produced by the flash bulb.

Advantageously, the test device according to the invention can be provided with an impact-resistant light-transmitting disc, in particular a glass disc, which is mounted on the light outlet area of the Fresnel lens. The use of such a filter allows the Fresnel lens and the test device according to the invention to be protected against environmental factors and destruction of the lens by impacts, leading to an increase in the operating reliability and the service life of the test device according to the invention.

Preferably, the Fresnel lens can be arranged in the test device according to the invention so that the divergence of the light emerging through the Fresnel lens is 0.5°, which corresponds to the divergence of the direct radiation of the solar radiation. As solar cells use direct radiation with a divergence of 0.5° while in operation, in a test method it is advantageous to illuminate them with light with a precise divergence of 0.5°.

In addition, the test device according to the invention can exhibit as measuring device a recording device such as an oscilloscope or an oscilloscope with a digital storage medium for example. The use of an oscilloscope or an oscilloscope with a (digital) storage medium makes it possible to record a measured characteristic such as for example the current-voltage characteristic of a PV concentrator module to be tested with the aid of paper or a digital storage medium. This allows the measured characteristics to be assigned to the tested PV concentrator module. Working with PV concentrator modules with known characteristics, such as known current-voltage characteristics for example, increases the operational reliability of the solar installation in which such modules are used.

A test device according to the invention is used in a test method according to the invention and a production method for a PV concentrator module according to the invention. This means that the PV concentrator modules are subjected to quality control and produced using a quality control. This makes it possible to supply PV concentrator modules with a high level of quality and known characteristics in each case.

In the following, embodiment examples of the invention are explained with reference to the attached drawings in which:

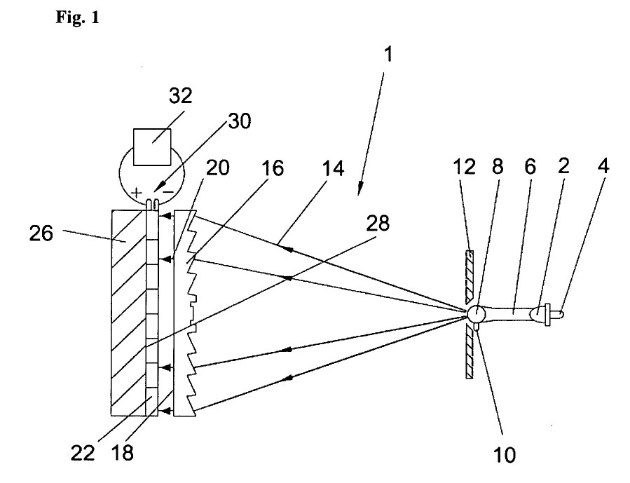

FIG. 1 shows a sectional view through a test device for a PV concentrator module according to a first form of embodiment (with a Fresnel lens, without a reflecting mirror, without a filter and without a glass disc);

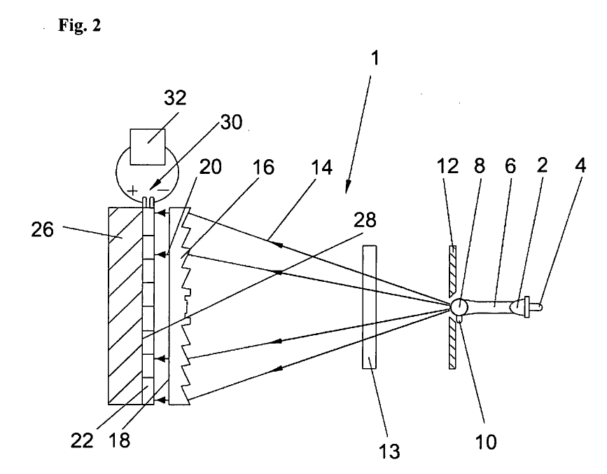

FIG. 2 shows a sectional view through a test device for a PV concentrator module according to a second form of embodiment (with a Fresnel lens, without a reflecting mirror, with a filter and without a glass disc);

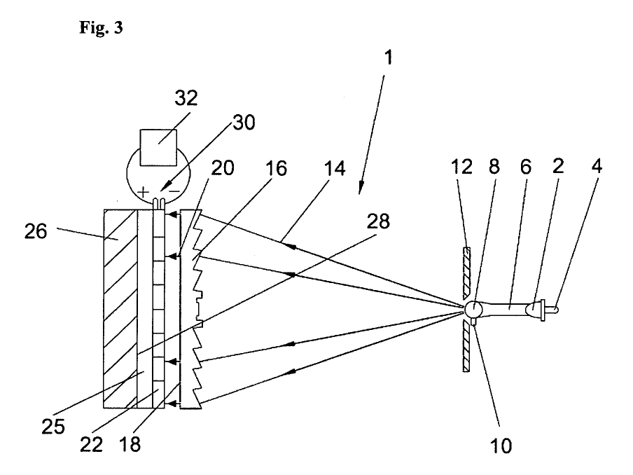

FIG. 3 shows a sectional view through a test device for a PV concentrator module according to a third form of embodiment (with a Fresnel lens, without a reflecting mirror, without a filter and with a glass disc);

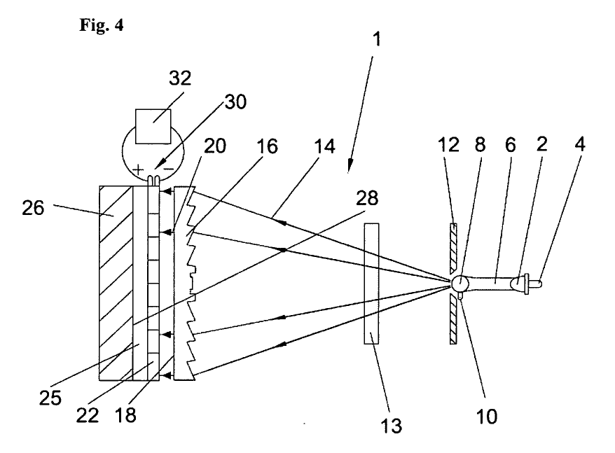

FIG. 4 shows a sectional view through a test device for a PV concentrator module according to a fourth form of embodiment (with a Fresnel lens, without a reflecting mirror, with a filter and with a glass disc);

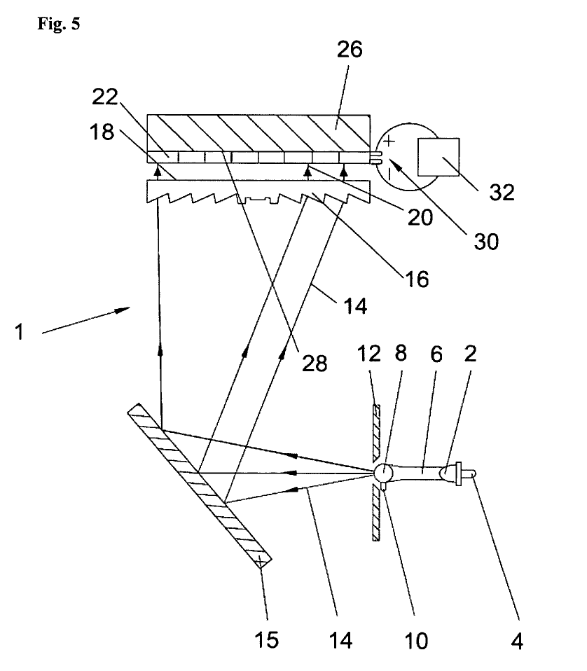

FIG. 5 shows a sectional view through a test device for a PV concentrator module according to a fifth form of embodiment (with a Fresnel lens, with a reflecting mirror, without a filter and without a glass disc);

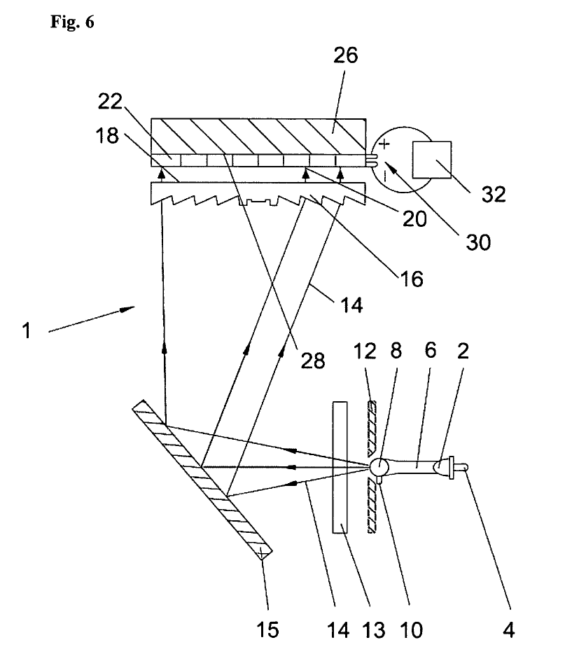

FIG. 6 shows a sectional view through a test device for a PV concentrator module according to a sixth form of embodiment (with a Fresnel lens, with a reflecting mirror, with a filter and without a glass disc);

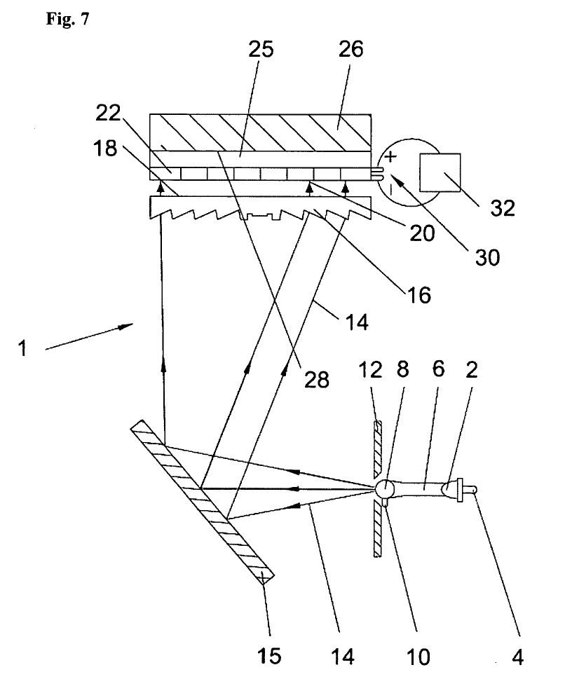

FIG. 7 shows a sectional view through a test device for a PV concentrator module according to a seventh form of embodiment (with a Fresnel lens, with a reflecting mirror, without a filter and with a glass disc); and

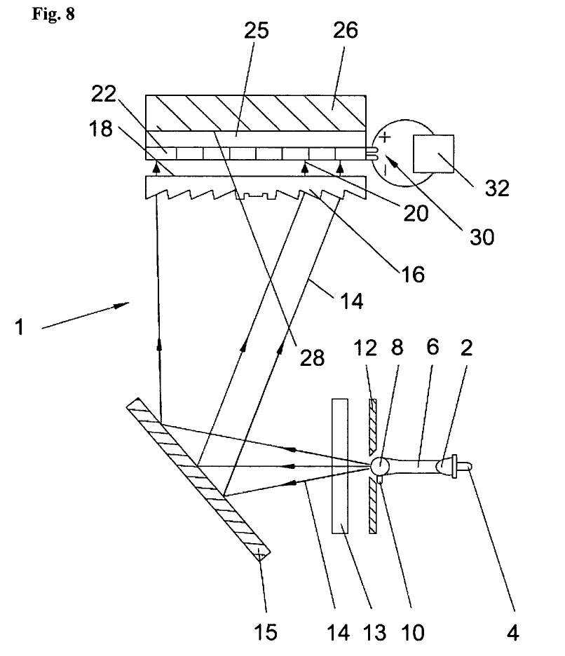

FIG. 8 shows a sectional view through a test device for a PV concentrator module according to a eighth form of embodiment (with a Fresnel lens, with a reflecting mirror, with a filter and with a glass disc); and

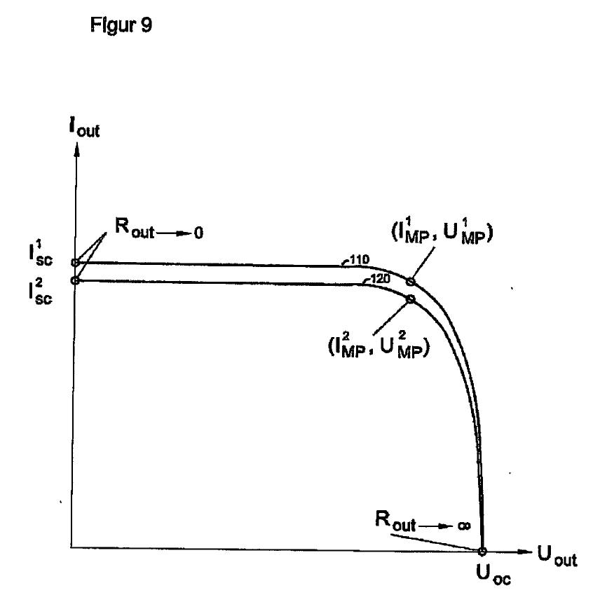

FIG. 9 shows a diagrammatic illustration of a recorded current-voltage characteristic for a PV concentrator module to be tested.

In the following description of the preferred forms of embodiment, the same references are used for corresponding parts.

FIG. 1 shows a test device 1 for a PV concentrator module 26 to be tested, in which a direct current (DC) light source 2, a quartz rod 6 and a flash bulb 8 are arranged in succession and coaxially.

The direct current (DC) light source 2 can be a high-power LED 3 which is used for preliminary positioning of a PV concentrator module 26 to be tested.

The quartz rod 6 serves as light guide for the LED 3 and is used in the embodiment example due to the high voltage which is advantageous for operation of the flash bulb 8 but should not exceed 1 kV if possible. The direct current (DC) light source 2 and the flash bulb 8 each exhibit a mains power connection 4 and 10 respectively for supplying the power during operation.

In the example the flash bulb 8 has a maximum irradiance of 1 kW/m². The flash bulb 8 can preferably generate light pulses the duration of which at 50% irradiance is no more than 1 ms. Preferably, the irradiance differs by no more than 3% of 1 kW/m² from light pulse to light pulse. The rate of repetition of the light pulses can be 1 pulse in 10 seconds or longer. In addition, the light produced by the flash bulb 8 also exhibits a spectrum which is similar to the spectrum of daylight. The above-mentioned properties of the flash bulb 8 result in the flash bulb 8 producing light which in its properties is very similar to the direct radiation of solar radiation.

Since when in operation the solar cells of a PV concentrator module to be tested work on the basis of the direct radiation, in a test method it is advantageous to illuminate them with light with properties similar to sunlight. In addition, it is expedient that the maximum irradiance of the light with which the solar cells are illuminated in a test method always remains the same in order to ensure comparability for operation from cell to cell or from PV concentrator module to PV concentrator module.

As can be seen in FIG. 1, a diaphragm 12 is arranged positioned by means of positioning marks or the like exactly coaxially with the flash bulb 8 and the direct current (DC) light source 2 (not shown) so that a bundle of light rays 14 is selected which preferably can exhibit an irradiance which differs by no more than 20% from the irradiance of the flash bulb 8. It is advantageous to use a bundle of light rays 14 which exhibits as uniform an irradiance as possible in order to obtain standardised test conditions for solar modules (e.g. 1000 W/m² at 25° C., quasi-parallel with an angle of 0.5 degrees according to the angle of incidence of the sunlight). Standardised tests allow the performance of a concentrator module to be compared with that of other solar modules.

With the aid of positioning marks or similar positioning methods, an optical system, here in the form of a Fresnel lens 16, is positioned coaxially with the direct current (DC) light source 2, the flash bulb 8 and the diaphragm 12 so that the opening of the diaphragm 12 is located on the optical axis of the Fresnel lens 16. In the example the diaphragm 12 is positioned about the focal point of the Fresnel lens 16 so that the divergence of a bundle of light rays 20 emerging from the Fresnel lens 16 is approximately 0.5°, comparable with the divergence of the sunlight impinging on the earth, with which the solar cells work while in operation.

On a light outlet area 18 of the Fresnel lens 16, between the Fresnel lens 16 and the PV concentrator module 26 to be tested, the test device 1 exhibits a neutral grey filter 22 for homogenisation of the irradiance of the bundle of light rays 20 over the light outlet area 18 of the Fresnel lens 16. The neutral grey filter 22 can produce homogenisation of the irradiance of the bundle of light rays 20 over the light outlet area 18 of the Fresnel lens 16 the fluctuations of which preferably lie within 5% (similar to the case of direct radiation). This neutral grey filter 22 can take a variety of forms, e.g. the form of a grid film.

The light outlet area 18 of the Fresnel lens 16 is preferably exactly the same size as or greater than the light admission area 28 of a PV concentrator module 26 to be tested so that complete irradiation of the light admission area 28 of a PV concentrator module 26 to be tested is possible with light generated by the flash bulb 8. To ensure complete irradiation, a PV concentrator module to be tested is additionally pre-positioned in the usual way with the aid of the positioning arrangement, which here exhibits the direct current (DC) light source 2 and one or more positioning marks (not shown), prior to irradiation with light generated by the flash bulb 8.

As shown in FIG. 1, the test device 1 exhibits an electrical connection 30 for connection and evaluation of the PV concentrator module 26 to be tested.

In addition, in the illustrated embodiments, the test device 1 exhibits a measuring device 32 which serves for measuring of characteristics such as for example a current-voltage characteristic of a PV concentrator module 26 to be tested. In the embodiment example shown here, the test device 1 also exhibits a recording device, here in the form of an oscilloscope 34 or an oscilloscope with a digital storage medium 36 (not shown in FIG. 1) for measuring and recording of at least one characteristic such as for example the current-voltage characteristic of a PV concentrator module 26 to be tested.

A recorded current-voltage characteristic, as shown for example in FIG. 9, describes the relationship between an output current Iₒᵤₜ, which is supplied by the PV concentrator module 26 to be tested when irradiated with light with similar qualities to sunlight and flows through an external load resistor Rₒᵤₜ, and an output voltage Uₒᵤₜ present at the load resistor Rₒᵤₜ with variable load resistance values Rₒᵤₜ.

To record such a current-voltage characteristic, the load resistance values Rₒᵤₜ are varied from 0Ω up to very large load resistance values by means of a variable resistor. A load resistance value of 0Ω means that the recorded measuring points of the current-voltage characteristic apply to a short circuit. In this case, no voltage is present at the output of the PV concentrator module 26 to be tested and then the output current Iₒᵤₜ corresponds to the maximum short circuit current I_{sc} which can be supplied by the PV concentrator module 26 to be tested.

The value of the load resistor Rₒᵤₜ is then increased until a value corresponding to approximately 0 A is measured for the output current Iₒᵤₜ. The corresponding value Uₒᵤₜ for the voltage at the load resistor Rₒᵤₜ for a current corresponding to 0 A is the open-circuit voltage U_{oc} of the PV concentrator module 26 to be tested.

When the load resistance value Rₒᵤₜ is increased starting with 0Ω, as a rule a constant value corresponding to the value of the short circuit current I_{sc} with the usual accuracy of measurement is measured over a relatively large range of load resistance values. Then, after passing through a point with the output current value I_{MP} and output voltage value U_{MP} at maximum power, the measured output current Iₒᵤₜ exhibits values which fall rapidly to 0 A when the load resistance Rₒᵤₜ is increased further.

In the manner described, the test device 1 makes it possible to record the precise current-voltage characteristics of a PV concentrator module 26 to be tested prior to final assembly thereof, so that reliable quality can be assured.

The recorded current-voltage characteristic in the initial state can also be used later as a reference for comparison with the corresponding characteristic of the same PV concentrator module at a later point in time. The differences from the starting characteristics can be used as a criterion to assess the operating state of such a PV concentrator module. This makes it possible to decide precisely whether the module will continue working reliably and effectively or whether it must be changed, leading to increased operational reliability of a solar installation working with such modules.

FIG. 9 shows a diagrammatic illustration of current-voltage characteristics of different PV concentrator modules prior to final assembly, in which line 110 stands for a first PV concentrator module with the values I¹_{sc}, I¹_{MP}, U¹_{MP} and line 120 stands for another PV concentrator module with the values I²_{SC}, I²_{MP} and U²_{MP}.

FIG. 9 could also show the current-voltage characteristics for one and the same PV concentrator module 26 in the initial state (line 110) and at a later point in time (line 120) after the PV concentrator module 26 has been in operation for a time. These lines would also have had the pattern shown in FIG. 9.

In a second form of embodiment shown in FIG. 2 a glass filter 13 is arranged between the diaphragm 12 and the Fresnel lens 16, allowing fine adjustment of the irradiance of the light coming from the flash bulb 8. As a result, the irradiance of the light 20 with which the PV concentrator modules 26 to be tested are illuminated can be adjusted precisely, leading to increased accuracy of the test device 1.

In a third form of embodiment shown in FIG. 3 an impact-resistant glass disc 25 is mounted on the light admission area 28 of the PV concentrator module to be tested between the neutral grey filter 22 and the PV concentrator module 26 to be tested in order to protect the Fresnel lens 16 against impacts and environmental factors, leading to increased operational reliability and accuracy of the test device 1.

A fourth form of embodiment of the test device 1 shown in FIG. 4 exhibits both a filter 13 like the second form of embodiment shown in FIG. 2, and an impact-resistant glass disc 25 like the third form of embodiment shown in FIG. 3.

A fifth form of embodiment of the test device 1 shown in FIG. 5 exhibits a similar structure to the first form of embodiment shown in FIG. 1 with the difference that a reflecting mirror 15 is arranged between the diaphragm 12 and the Fresnel lens 16 to deflect the bundle of light rays 14. In the example the reflecting mirror forms an angle of 45° with the optical axis of the Fresnel lens 16. When the reflecting mirror 15 is used, the direct current (DC) light source 2, the quartz rod 6, the flash bulb 8 and the diaphragm 12 are arranged coaxially. The optical system which also takes the form of the Fresnel lens 16 here, can be arranged positioned precisely perpendicularly to the diaphragm 12 and coaxially with the neutral grey filter 22 and the PV concentrator module 26 to be tested with the aid of positioning marks for example (not shown here). The use of the reflecting mirror 15 allows the test device 1 for a PV concentrator module to be made smaller, leading to a reduction in the cost of production of such a test device 1.

A sixth form of embodiment of the test device 1 shown in FIG. 6 exhibits a similar structure to the fifth form of embodiment shown in FIG. 5 with the difference that the glass filter 13 is arranged between the diaphragm 12 and the reflecting mirror 15, allowing fine adjustment of the illuminance of the light coming from the flash bulb 8. This allows precise adjustment of the irradiance or frequency of the light 20 with which the PV concentrator modules 26 to be tested are illuminated, leading to an increase in the precision of the test device 1 according to the invention.

A seventh form of embodiment of the test device 1 shown in FIG. 7 has a similar structure to the form of embodiment shown in FIG. 5 with the difference that an impact-resistant glass disc 25 is arranged mounted on the light admission area 28 of the PV concentrator module to be tested between the neutral grey filter 22 and the PV concentrator module 26 to be tested in order to protect the Fresnel lens 16 against impacts and environmental factors, leading to increased operational reliability and accuracy of the test device 1.

An eighth form of embodiment of the test device 1 shown in FIG. 8 exhibits both a filter like the sixth form of embodiment shown in FIG. 6, and an impact-resistant glass disc 25 like the seventh form of embodiment shown in FIG. 7.

The test device 1 can be arranged and accommodated in a metal housing (not shown in the drawings).

The test device 1 described here can be used advantageously in a production method described in greater detail in German patent application DE 10 2005 033 272.2 for producing PV concentrator modules for quality assurance purposes. For further details of these PV concentrator modules 26, reference should be made expressly to this patent application.

1. Test device (1) for a PV concentrator module (26) with a first light source (8) for generating a light simulating solar radiation,
an optical system which bundles the light rays emerging from the first light source into a light bundle with a divergence of the individual light rays of less than 2° and is suitable for aiming this light bundle onto a light admission area of the PV concentrator module,
and a measuring device (32) for measuring an output signal of the PV concentrator module (26) irradiated by the light bundle.

2. Test device according to claim 1, characterised in that in the area of the light bundle serving for irradiation of the PV concentrator module the test device exhibits an irradiance of approximately 1 kW/m² ±3% or an irradiance with values which lie in a range from approximately 0.75 kW/m² to 1.25 kW/m².

3. Test device according to one of the preceding claims, characterised in that in the area intended for irradiation of a light admission area of the PV concentrator module the light bundle has an essentially uniform areal distribution of the irradiance.

4. Test device according to one of the preceding claims, characterised in that the first light source exhibits a flash bulb (8).

5. Test device according to one of the preceding claims, characterised in that the first optical system has a diaphragm for selecting a diverging bundle of a roughly punctiform first light source (8) and a lens (16) for converting the diverging bundle into the light bundle with quasi-parallel light rays for irradiation of a light admission area of the PV concentrator module.

6. Test device according to one of the preceding claims, characterised in that the first optical system exhibits a Fresnel lens (16) to parallelise of a divergent light beam emerging from the first light source for the purpose of generating a quasi-parallel light bundle simulating the incident sunlight with a divergence of less than 2°, preferably of approximately 0.5°.

7. Test device according to one of the preceding claims, characterised in that a positioning device is provided with the aid of which the PV concentrator module (26) to be tested can be aligned precisely with the first light source (8).

8. Test device according to claim 7, characterised in that the positioning device exhibits a light source (2) which sends out light rays over the same path as the light rays sent out by the first light source (8) to simulate sunlight, wherein the position of the PV concentrator module (26) to be tested can be aligned with reference to the light rays of the positioning device.

9. Test device according to claim 8, characterised in that the light source of the positioning device is a second light source (2) the light rays of which can be brought into the beam path of the first light source (8) by means of a light guide (6).

10. Test device according to claim 9, characterised in that the second light source exhibits a direct current (DC) light source (2) and the light guide exhibits a quartz rod (6).

11. Test device according to claim 10, characterised in that the first light source exhibits a flash bulb (8) which is arranged coaxially with the direct current (DC) light source (2) and the quartz rod (6), in particular with an irradiance of around 1 kW/m² ±3%.

12. Test device according to one of the preceding claims, characterised in that the light source of the positioning device is a light-emitting diode (LED).

13. Test device according to one of the preceding claims, characterised in that the first optical system exhibits a filter (22) for the quasi-parallel light bundle for generating an essentially identical areal distribution of the irradiance.

14. Test device according to claim 13, characterised in that the filter is a neutral grey filter (22) for converting the bundle of quasi-parallel light rays (20) into a bundle of quasi-parallel light rays with a quasi-uniform areal distribution of its irradiance.

15. Test device according to one of the preceding claims, characterised by a connecting device (30) which exhibits an electronic circuit for connecting the PV concentrator module (26) to be tested.

16. Test device according to claim 15, characterised in that the electronic circuit exhibits a selectively variable resistor.

17. Test device according to one of the preceding claims, characterised in that the measuring device (32) is designed to record at least one characteristic, in particular a current-voltage characteristic, of the PV concentrator module (26) to be tested.

18. Test device according to one of the preceding claims, characterised in that the test device (1) exhibits a second optical system (12) for deflecting the light rays from the first light source.

19. Test device according to claim 18, characterised in that the second optical system exhibits a reflecting mirror (15) arranged between the diaphragm (12) and the lens (16) for deflecting the light produced by the flash bulb (8).

20. Test device according to one of the preceding claims, characterised in that the test device (1) exhibits a filter (13) arranged parallel with the diaphragm (12) between the diaphragm (12) and the lens (16) or between the diaphragm (12) and the reflecting mirror (15).

21. Test device according to one of the preceding claims, characterised in that an impact-resistant light-transmitting disc, in particular a glass disc (25), is mounted on the light outlet area (18) of the first optical system, in particular on the light outlet area (18) of the Fresnel lens (16).

22. Test device according to one of the preceding claims, characterised in that the measuring device (32) exhibits a recording device for recording the measured signal, in particular an oscilloscope (34).

23. Test device for a PV concentrator module (1) according to claim 22, characterised in that the oscilloscope (34) exhibits a storage medium (36) which is in particular digital.

24. Test method for testing a PV concentrator module, characterised by bundling the light rays from a first light source to form a roughly parallel light bundle, irradiation, in particular complete irradiation, of the light admission area of the PV concentrator module to be tested with the roughly parallel light bundle and measurement of the signal delivered by the PV concentrator module.

25. Production method for production of a PV concentrator module, characterised in that prior to and/or after the final assembly of a PV concentrator module, the PV concentrator module is tested by means of a test device according to one of claims 1 to 24 for quality assurance purposes.
